(19) United States
(12) Patent Application Publication
(10) Pub. No.: US 2006/0208364 A1
(43) Pub. Date: Sep. 21, 2006

(54) LED device with flip chip structure

(76) Inventors: Chien-Jen Wang, Kaohsiung City (TW); Nai-Wen Chang, Jhongli City (TW); Wei-Jen Wang, Madou Township (TW); Kuo-Chun Chiang, Taoyuan CIty (TW); Chuan-Ming Chang, Hsinchu City (TW)

Correspondence Address: LIN & ASSOCIATES INTELLECTUAL PROPERTY, P.O. BOX 2339, SARATOGA, CA, 95070-0339, US

(21) Appl. No.: 11/084,580

(22) Filed: Mar. 19, 2005

(51) Int. Cl. H01L 23/48

(52) U.S. Cl. 257/778

(57) ABSTRACT

The present invention provides an LED device with a flip chip structure. The LED device comprises an insulating substrate, an LED flip chip, a molding compound, a first conductive element, and a second conductive element. The LED flip chip is electrically connected to the connection pads on the insulating substrate via the two conductive elements. The P-type and N-type electrodes are connected to the P-type and N-type electrodes layers, respectively. The invention need not require a conventional wire bonding process. It not only increases the yield rate of the product but also makes the product more compact.

### FIELD OF THE INVENTION

The present invention generally relates to a light emitting diode (LED) device, and more specifically to an LED device with a flip chip structure.

### BACKGROUND OF THE INVENTION

FIG. 1 shows a cross-sectional structure of a conventional surface-mount device (SMD) type LED device.

In a conventional SMD-type LED packaging structure, an LED die 13 is attached to a packaging substrate 11. The positive and negative electrodes of the LED die 13 are connected through gold or aluminum wires to a positive pad 111 and a negative pad 112 on the packaging substrate, respectively. The LED die 13 and the gold wires 12 are then covered with a transparent resin 14 to isolate them from the outside environment. Only the metal pads or the connection pins 111 and 112 are left exposed for power source connection. Wherein, the top layer of the LED die 13 is a passive protection layer 133.

A wire bonding process during packaging is required for the conventional SMD-type LED device. The thickness AA′ of the package fabricated by the conventional method is as large as 0.6 mm. The above scheme not only lowers the productivity but also wastes a room required for the bonding wires. This type of packaging structure is not good for device miniaturization.

FIG. 2 shows a cross-sectional view and a top view of another conventional LED device. This conventional surface mount LED device 200 with a flip chip packaging structure was disclosed in Taiwan Patent 548857. The device 200 includes two parts: the first part is an LED dice 210 having a flip chip structure, and the second part is an insulating substrate 220 for mounting the LED dice 210. The LED dice 210 in the LED device 200 is attached to the first electrode layer 221 and the second electrode layer 222 on the insulating substrate 220 through the first bonding pad 211 and the second bonding pad 212 using a soldering technique. The LED dice 210 in the LED device 200 has a flip chip structure and exhibits a brighter intensity than a conventional SMD-type LED device. Furthermore, the LED dice 210 is mounted onto the insulating substrate 220 with a flip chip technique. Therefore, a wire bonding process required for a conventional LED package is eliminated.

However, the metal reflective layers 213 and 214 and the ohmic contact layers (not shown here) of the LED device 200 are separately processed and therefore a passive protection layer is required near the end of the process. This kind of manufacturing process is complicated and requires a long manufacturing time. Moreover, the miniaturization capability of the LED device 200 is limited though it is still better than conventional LED devices.

Since the conventional LED devices have many drawbacks, it is important to provide an LED device to lower the manufacturing cost, increase the productivity, reduce the package thickness, and increase the brightness.

### SUMMARY OF THE INVENTION

The present invention has been made to overcome the above drawbacks of the conventional LED devices. The primary objective of the present invention is to provide an LED device with a flip chip packaging structure. The LED device of the present invention comprises an insulating substrate, an LED flip chip, a molding compound, a first conductive element, and a second conductive element. The insulating substrate has two side edges, a top surface, a down surface, a P-type electrode layer, and an N-type electrode layer. Each electrode layer is disposed on one side edge of the insulating substrate and extended to cover a portion of the top and down surfaces. The first conductive element is located on the top of the P-type electrode. The second conductive element is located on the top of the N-type electrode.

According to the present invention, the LED flip chip having a P-type electrode and an N-type electrode is formed on the first conductive element and the second conductive element. The molding compound covers the LED flip chip, the first conductive element, and the second conductive element. Wherein, the LED flip chip is electrically connected to the connection pads on the insulating substrate via the two conductive elements. The P-type and N-type electrodes are connected to the P-type and N-type electrodes layers, respectively.

Another objective of the present invention is to provide a manufacturing method for the flip chip LED devices. This method comprises the following steps: (a) Provide an insulating substrate having two side edges, a top surface, a down surface, a P-type electrode layer, and an N-type electrode layer. Wherein, each electrode layer is disposed on one side edge of the insulating substrate and extended to cover a portion of the top and down surfaces. (b) Dispose a first conductive element and a second conductive element on top of the P-type and N-type electrodes layers, respectively. (c) Dispose an LED flip chip on the first conductive element and the second conductive element. The LED flip chip has a P-type electrode and an N-type electrode. The P-type and N-type electrodes of the LED flip chip are connected to the first conductive element and the second conductive element, respectively. (d) Sinter the first conductive element and the second conductive element. (e) Inject a molding compound to cover the LED flip chip, the first conductive element, and the second conductive element, and then bake the molding compound.

A unique feature of the present invention is that the wire bonding process is eliminated in the manufacturing process. The room required for the wire bonding process is then saved. The thickness of the LED device of the present invention is more than 50% reduced as compared to a conventional LED device of same specification. Besides, the multiple reflective films in the LED flip chip significantly increase the brightness of emitted light. These films can also act as protection layers, which eliminate the need of a passive protection layer during the manufacturing process. Therefore, the LED device of the present invention has the advantages of low cost, high productivity, and suitability for device miniaturization.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows a cross-sectional structure of a conventional SMD-type LED device.

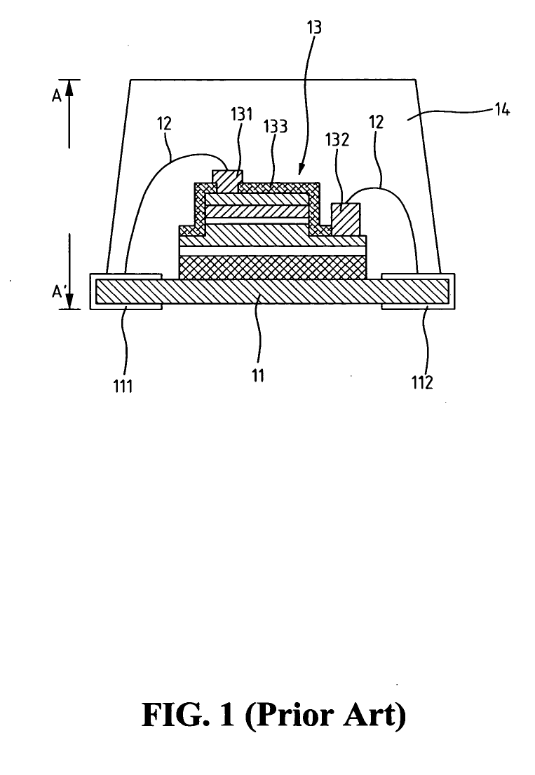

FIG. 2 shows a cross-sectional view and a top view of another conventional LED device.

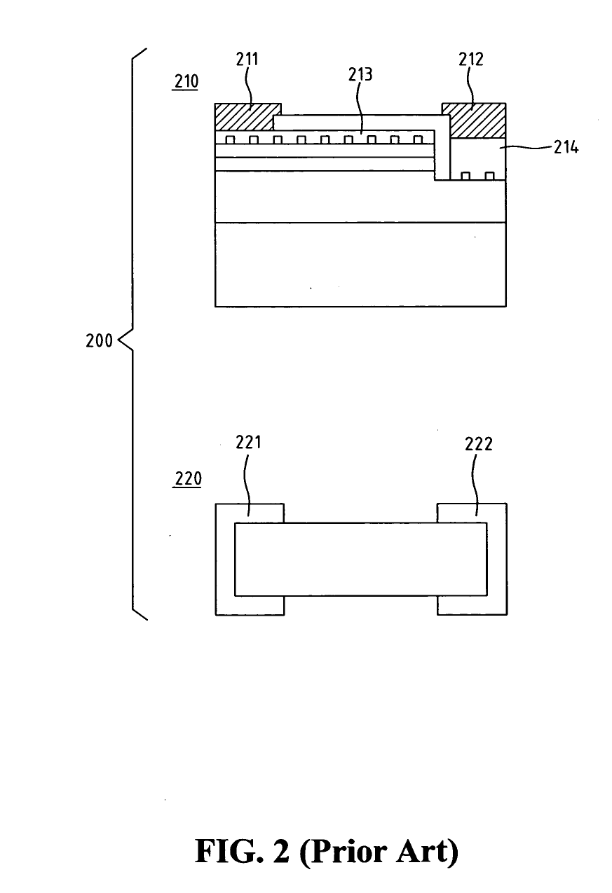

FIG. 3 shows a cross-sectional view of a flip chip LED device of the present invention.

FIG. 4 shows a cross-sectional view of another flip chip LED device of the present invention.

FIGS. 5A-5D show a manufacturing method of the LED device shown in FIG. 3.

### DETAILED DESCRIPTION OF THE PREFERRED EMBODIMENTS

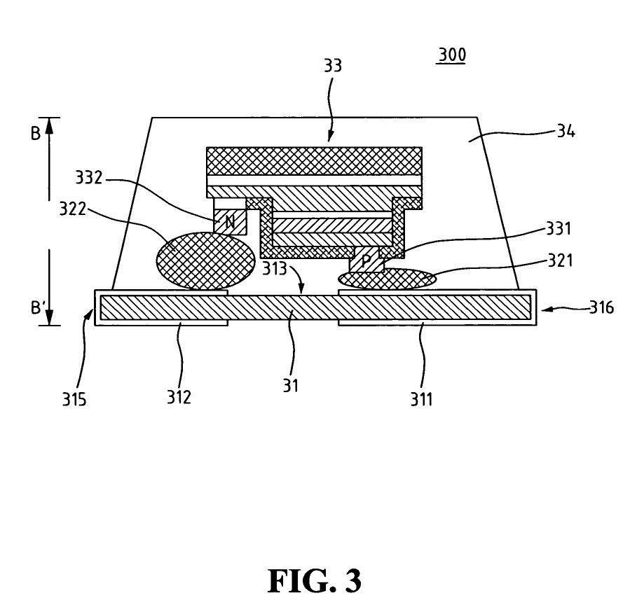

FIG. 3 depicts a cross-sectional view of a flip chip LED device of the present invention. As shown in FIG. 3, a flip chip LED device 300 comprises an insulating substrate 31, an LED flip chip 33, a molding compound 34, a first conductive element 321, and a second conductive element 322. The insulating substrate 31 has two side edges 315 and 316, a top surface 313, a down surface 314, a P-type electrode layer 311, and an N-type electrode layer 312. Every electrode layer is disposed near one side edge of the substrate 31 and extended to cover a portion of the top surface 313 and down surface 314 of the substrate 31. The P-type electrode layer 311 and the N-type electrode 312 can be used as connection pads to the outside electrical power.

The first conductive element 321 is located on the top of the P-type electrode layer 311. The second conductive element 322 is located on the top of the N-type electrode layer 312. The LED flip chip 33 having a P-type electrode 331 and an N-type electrode 332 is formed above the first conductive element 321 and the second conductive element 322. The LED flip chip 33 is electrically connected to the connection pads on the insulating substrate via the two conductive elements 321 and 322. The P-type electrode 331 and N-type electrode 332 are connected to the P-type electrode layer 311 and N-type electrode layer 312, separately. According to the present invention, the LED flip chip 33 is fixed by the conductive elements 321 and 322 instead of the conventional bonding wires. Elimination of the wire bonding process not only expedites the manufacturing process but also effectively reduces the production cost. These conductive elements 321 and 322 are a pasty conductive material, and are solidified after a proper heat treatment. These materials include silver paste, tin paste, gold ball, and tin ball etc.

Lastly, the molding compound 34 is shaped with a molding technique, and covers the LED flip chip 33, the first conductive element 321, and the second conductive element 322 to protect them from scratch, oxidation etc.

A unique feature of the present invention is that the wire bonding process is eliminated in the manufacturing process. The room required for the wire bonding process is then saved in the LED device 300. The normal thickness of the conventional SMD-type LED device is 0.6 mm. The thickness of the LED device of the present invention BB′ is 0.25 mm. This small thickness is suitable for device miniaturization.

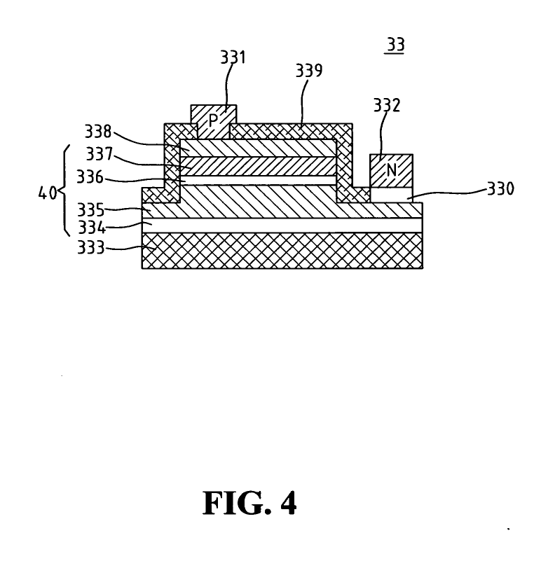

As shown in FIG. 4, the lowest layer of the LED flip chip 33 is a transparent substrate 333. The emitted light from the LED of the present invention passes through the transparent substrate 333 to the outside. The transparent substrate 333 must be made of highly transparent materials. In general, blue diamond is a good material for the transparent substrate 333 because it is highly transparent and suitable for growing GaN epitaxial layer.

A low temperature GaN nucleation layer 334 of 200-500 Å thick is on top of the transparent substrate 333. Above that is a 2-5 μm thick N-type GaN cladding layer 335. A 0.05-0.07 μm thick InGaN multiple quantum well 336 is located on the N-type GaN cladding layer 335. A 0.1-0.7 μm thick P-type GaN cover layer 337 is formed on the InGaN multiple quantum well 336.

A light emitting layer 40 is formed by the transparent substrate 333, nucleation layer 334, N-type GaN cladding layer 335, InGaN multiple quantum well 336, and P-type GaN cover layer 337.

A transparent conductive layer (TCL) 338 is disposed on the P-type GaN cover layer 337. According to the present invention, a conventional Ni/Au material is adopted for the TCL 338. It receives a high temperature sintering process at 500-550° C.

An N-type ohmic contact layer 330 is formed on the N-type GaN cladding layer 335. A multiple reflective film 339 covers the transparent conductive layer 338, the N-type GaN cladding layer 335, and the N-type ohmic contact layer 330. When lights emitted from the light-emitting layer 40, not all of them travel in one same direction. The LED flip chip 33 reverses the original forward trajectory of the emitted light through the multiple reflective film 339, and guides the lights towards the transparent substrate. The multiple reflective film 339 is made of a pair of high refractive material (H) and low refractive material (L). The thickness of each reflective film is equal to one fourth of the wavelength λ. When the multiple reflective film is repeatedly deposited with a sequence of (HL) (HL) . . . (HL)H, a very good reflectivity can be obtained. The total thickness of the multiple reflective film is equal to (λ/4)×(2×N+1). Wherein, A is the wavelength of the light emitted from LED. N is the number of (HL) pairs, which is about 5˜15 pairs. Therefore, the total thickness of the multiple reflective film is equal to (11/4) λ˜(31/4) λ. According to the present invention, the materials used for the multiple reflective film 339 include TiO₂/SiO₂, Al₂O₃/SiO₂, Si₃N₄/SiO₂ etc.

Lastly, there are P-type electrode 331 and N-type electrode 332 on top of the transparent conductive layer 338 and N-type ohmic contact layer 330, respectively. The multiple reflective film 339 is made contacted with a portion of P-type electrode 331, N-type electrode 332, and N-type ohmic contact layer 330.

According to the present invention, the emitted lights originally traveling towards the transparent conductive layer 338 are reflected to the transparent substrate 333 through the multiple reflective film 339. These lights are then combined with the lights originally emitted towards the transparent substrate 333. Therefore, the intensity of light coming from the LED to the transparent substrate 333 is greatly enhanced.

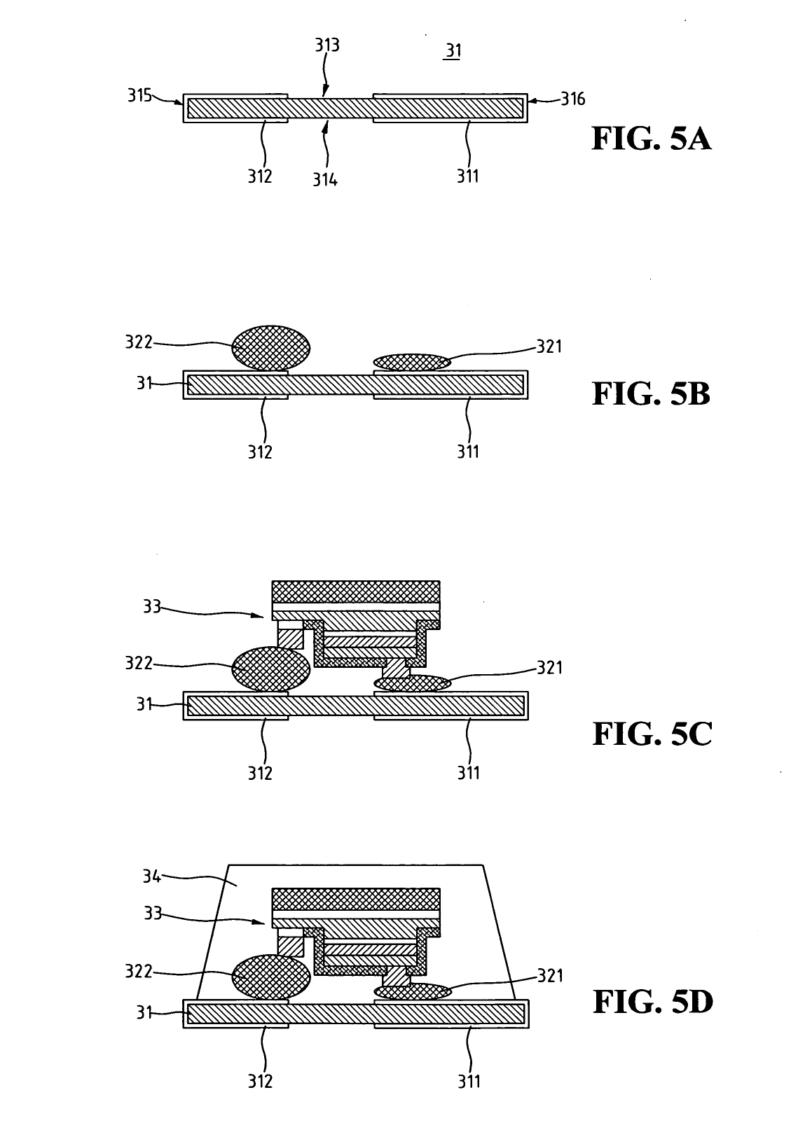

FIGS. 5A-5D depicts a manufacturing method of the LED device described above. Firstly, an insulating substrate 31 having two side edges 315 and 316, a top surface 313, and a down surface 314. As shown in FIG. 5A, a P-type electrode layer 311 and an N-type electrode layer 312 are formed on the side edges 315 and 316 of the insulating substrate 31 and extended to cover a portion of the top surface 313 and the down surface 314, respectively. The insulating substrate 31 can be made of epoxy resin or polyimide (PI) or bismaleimide triazine resin (BT resin) or polyphenylene oxide (PPO) or polytetrafluoroethylene (PTFE) or polycyanate and etc.

Next, a first conductive element 321 and a second conductive element 322 are disposed on top of the P-type electrode layer 311 and N-type electrodes layer 312, respectively. The method of forming the conductive element can vary with the material property of the conductive element. For example, an epoxy dispenser is used to dispose the material if the conductive element is a silver paste. If the conductive element is a tin paste, a mask is used first to define the areas to be pasted. Then, a coater is used to dispose the tin paste on those areas. If the conductive element is a gold ball or a tin ball, a ball planting equipment is used to dispose the ball, as shown in FIG. 5B.

Subsequently, an LED flip chip 33 (shown in FIG. 3) is placed on the first conductive element 321 and the second conductive element 322. The P-type electrode 331 and N-type electrode 332 of the LED flip chip are connected with the first conductive element 321 and the second conductive element 322, respectively.

Then, the first conductive element 321 and the second conductive element 322 are sintered. The purpose of the sintering is to solidify the conductive elements and fix the LED flip chip 33 on the substrate. Another purpose is to form electrical connections between P-type electrode 331 and P-type electrode layer 311 and between N-type electrode 332 and N-type electrode layer 312 through the first conductive element 321 and the second conductive element 322, respectively.

Lastly, a molding compound 34 is injected to cover the LED flip chip 33, the first conductive element 321, and the second conductive element 322. Then, the molding compound 34 is baked to fix the whole packaging module, as shown in FIG. 5D. The molding compound 34 used for packaging technology can be chosen from the group of epoxy resin, transparent epoxy resin, and semi-transparent epoxy resin etc.

A unique feature of the present invention is that the wire bonding process is eliminated in the manufacturing process. The room required for the wire bonding process is then saved. The thickness of the LED device of the present invention is more than 50% reduced as compared to a conventional LED device of same specification. Besides, the multiple reflective films in the LED flip chip have a protection function, which eliminate the need of a passive protection layer during the manufacturing process. In general, the LED device of the present invention has a simple manufacturing process and short manufacturing cycle time. It offers the advantages of reducing manufacturing cost, increasing productivity, reducing device thickness, and increasing LED intensity.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A light emitting diode (LED) device with a flip chip structure, comprising:
an insulating substrate having two side edges, a top surface, a down surface, a P-type electrode layer, and an N-type electrode layer, wherein each said electrode layer is disposed on a said side edge of said insulating substrate and extended to cover a portion of said top surface and said down surface;
a first conductive element being located on the top of said P-type electrode layer;
a second conductive element being located on the top of the N-type electrode layer;
an LED flip chip having a P-type electrode and an N-type electrode, wherein said LED flip chip is disposed on said first conductive element and said second conductive element; and
a molding compound covering said LED flip chip, said first conductive element, and said second conductive element, wherein said LED flip chip forms electrical connections between said P-type electrode and said P-type electrode layer and between said N-type electrode and said N-type electrode layer through said first conductive element and said second conductive element, respectively.

2. The LED device with a flip chip structure as claimed in claim 1, wherein said LED flip chip further comprises:
a transparent substrate, wherein lights emitted from said LED flip chip travel through said transparent substrate to the outside;
a light emitting layer formed on said transparent substrate, wherein said light emitting layer comprises a nucleation layer, an N-type GaN cladding layer, an InGaN multiple quantum well, and a P-type GaN cover layer;
a transparent conductive layer formed on said light emitting layer, and said P-type electrode is disposed on said transparent conductive layer;
an N-type ohmic contact layer formed on said N-type GaN cladding layer, and said N-type electrode is disposed on said N-type ohmic contact layer; and
a multiple reflective film made of a pair of high refractive material (H) and low refractive material (L), wherein said multiple reflective film is repeatedly deposited with a sequence of (HL) (HL) . . . (HL)H and covers said transparent conductive layer and said N-type GaN cladding layer, and said multiple reflective film is further made contacted with a portion of said P-type electrode, said N-type electrode, and said N-type ohmic contact layer.

3. The LED device with a flip chip structure as claimed in claim 1, wherein said insulating substrate is a printed circuit board.

4. The LED device with a flip chip structure as claimed in claim 1, wherein said conductive element is chosen from the group of silver paste, tin paste, gold ball, and tin ball.

5. A manufacturing method for flip chip LED devices, comprising the steps of:
(a) providing an insulating substrate having two side edges, a top surface, a down surface, a P-type electrode layer, and an N-type electrode layer, wherein each said electrode layer is disposed on one said side edge of said insulating substrate and extended to cover a portion of said top and down surfaces;
(b) disposing a first conductive element and a second conductive element on said P-type and N-type electrodes layers, respectively;
(c) disposing an LED flip chip on said first conductive element and said second conductive element, wherein said LED flip chip has a P-type electrode and an N-type electrode, said P-type and N-type electrodes are connected to said first conductive element and said second conductive element, respectively;
(d) sintering said first conductive element and said second conductive element; and
(e) injecting a molding compound to cover said LED flip chip, said first conductive element, and said second conductive element, and then bake said molding compound.

6. The manufacturing method for flip chip LED devices as claimed in claim 5, wherein said insulating substrate is made of one of epoxy resin, polyimide, bismaleimide triazine resin, polyphenylene oxide, polytetrafluoroethylene, and polycyanate.

7. The manufacturing method for flip chip LED devices as claimed in claim 5, wherein said molding compound is chosen from the group of epoxy resin, transparent epoxy resin, and semi-transparent epoxy resin.
